(19) United States
(12) Patent Application Publication
(10) Pub. No.: US 2015/0040691 A1
(43) Pub. Date: Feb. 12, 2015

(54) METHOD AND SYSTEM OF MONITORING A POTENTIOMETRIC MEASURING PROBE

(71) Applicant: Mettler-Toledo AG, Greifensee (CH)

(72) Inventor: Philippe Ehrismann, Uster (CH)

(21) Appl. No.: 14/523,385

(22) Filed: Oct. 24, 2014

Related U.S. Application Data
(62) Division of application No. 13/109,110, filed on May 17, 2011.
Application No. 13/109,110 is a continuation of application No. PCT/EP2009/065644, filed on Nov. 23, 2009.

(30) Foreign Application Priority Data
Nov. 24, 2008 (DE) 102008058804.0

(51) Int. Cl. G01D 21/00; G01R 1/067; G01N 27/00

(52) U.S. Cl. CPC G01D 21/00; G01N 27/00; G01R 1/067
USPC 73/866.5

(57) ABSTRACT

Method and system of monitoring a measuring probe which is in contact with a measurement medium and registers a measurement value of the measurement medium, wherein the method comprises determining and evaluating time-dependent values of a first and a second parameter, wherein the first parameter responds faster than the second parameter to changes in a process to which the measurement medium is subjected, and wherein both of the parameters are probe-specific parameters.

### CROSS-REFERENCE TO RELATED APPLICATIONS

This application is a divisional of U.S. Ser. No. 13/109,110, filed on 17 May 2011, which is in turn a by-pass continuation under 35 USC §120 of PCT/EP2009/065644, filed 23 Nov. 2009, which is in turn entitled to benefit of a right of priority under 35 USC §119 from German patent application 102008058804.0, which was filed 24 Nov. 2008. The content of each of the applications is incorporated by reference as if fully recited herein.

### TECHNICAL FIELD

The exemplary embodiments of the present invention concern a method of monitoring a measuring probe. More particularly exemplary embodiments of the present invention concern a method of monitoring an ion-sensitive, amperometric, potentiometric, or optical measuring probe.

### BACKGROUND

Examples of such measuring probes are pH-, O₂-, CO₂-, or conductivity-measuring probes, among others, which are used in the laboratory as well as for the monitoring and controlling of process systems in many branches of industry including, besides the chemical and pharmaceutical industries, for example also the food industry and the cosmetics industry.

It is sufficiently well known that measurement probes of this kind will age or will change their ability to function over time due to events that are connected to the measurement medium or occur in the measurement medium. The measurement probe can, for example, be attacked by aggressive measurement media or can suffer changes under extreme process conditions. In the case of a pH-measuring probe, the measurement medium can for example penetrate by way of a liquid junction into the measuring probe and change the components of the latter.

The known state of the art offers a variety of approaches and methods for a quantitative assessment of the changes that these events cause in the measuring probe.

A method of calculating the wear-dependent remaining operating life of an electrochemical measuring probe is disclosed in DE 102 09 318 A1. The method is based on the fact that the wear-related deterioration of a measuring probe manifests itself in the change of one or more parameters that are relevant to its function. The parameters being considered are different calibration parameters of a pH- or oxygen-measuring probe.

A method disclosed in EP 1 550 861 A1 allows the state of a measuring probe to be determined while taking into account extraneous temperature effects of the kind that occur in the cleaning of the measurement probe under process conditions.

The aforementioned methods are based primarily on an assessment of the events that have already occurred in comparison to a given total operating life. They give no information about the current condition of the measuring probe or the stability of the measurement values.

In these methods, the total operating life is in general an estimated value based on prior experience. In a process system, there is often a large number of measuring probes in use. Every premature, and thus unnecessary, exchange of a measuring probe increases the costs of the process. Under unfavorable circumstances, a failure of a measuring electrode can even lead to an interruption of the process.

A pH-measuring electrode described in EP 1 176 419 A2 has two reference elements which are arranged so that an impoverished condition of the electrolyte reaches one of the reference elements before the other.

A pH-measuring electrode described in EP 1 219 959 A1 likewise has two reference elements, wherein the reference elements differ from each other in their stability, so that an advancing impoverishment of the electrolyte affects one reference element faster than the other.

Detecting the impoverishment of the electrolyte thus requires a change in the design of the measuring probe. Furthermore, these methods provide no information about the quality and/or stability of the measurement signal.

Besides information regarding the ability to function correctly and regarding the remaining operating life, it is also important for the user to have information about the current operating condition of a measuring probe and about the stability of the measurement values obtained from it. It would therefore be desirable to be able to determine and more precisely indicate the current operating condition of a measuring probe.

### SUMMARY

This task is solved by a method for the continuous monitoring of a measuring probe and by a measuring system with the capability to implement the method.

The exemplary method of monitoring a measuring probe, specifically an ion-sensitive, amperometric, potentiometric or optical measuring probe which is in contact with a measurement medium and serves to acquire at least one measurement value of the measurement medium, comprises several steps. First, the values of at least one first parameter are determined as a function of time. Based on these values, the values for the time derivative or slope of the first parameter and a first absolute value of the slope are calculated. The first absolute value is compared to a first threshold value. As soon as the first absolute value reaches or exceeds the first threshold value, a first point in time is registered. Starting at this first point in time, the first parameter is monitored until the first absolute value falls back below the first threshold value, at which point a second point in time is registered. From this second point in time, the values of at least one second parameter are determined as a function of time, and based on these values, the time derivative or slope of the second parameter and a second absolute value of the slope are calculated. The second absolute value is monitored until it falls below the second threshold value. When this happens, a third point in time is registered. Based on the first, second and/or third points in time, a monitoring quantity is determined. The method relies on the fact that the first parameter responds faster to a change of the measurement medium than the second parameter. Both parameters are probe-specific parameters, i.e. parameters that are specific to the probe and/or parameters whose quality and/or accuracy change as a result of aging of the probe, and whose values respond or react to a change of the measurement medium and/or the measurement conditions. Preferably, the first and second parameters are mutually independent parameters which have essentially no influence on each other.

The exemplary method according to the invention provides the ability to monitor the specific behavior, the stability as well as the reliability of the measurement values of an individual measuring probe by monitoring at least two parameters. Furthermore, events that occur over a short time and/or unintentionally can also be detected with the measuring probe.

The exemplary method according to the invention can further comprise the acquisition and determination of the values of at least one further parameter, wherein a relationship is established between the latter values and those of the first and/or second parameters. Thus, the exemplary method according to the invention can include a comparison of the respective behaviors of measurement values of two or more probe-specific parameters.

In an exemplary embodiment of the method, the relative response behavior of the measuring probe can represent the monitoring quantity. The determination of the relative response behavior includes the following steps: determine a first measurement value at the first point in time and a second measurement value at the third point in time. Next, the difference between the first and second measurement values as well as the time interval between the third and first points in time are determined.

As an alternative the relationship, i.e. the mathematical ratio, of a first measurement value to a third and a fourth measurement value can be determined which are measured or determined at a fourth or fifth point in time. The fourth or fifth point in time can be defined as the points in time when the measurement value of the probe has reached about 95% or about 98% of the jump or difference between the first and the second measurement value. By means of the fourth and/or the fifth point in time, a probe-specific quantity can be determined from which a conclusion can be drawn about the response time and thus also about the state of aging of the measuring probe.

Using this kind of a method for monitoring a measuring probe is advantageous, as it is essentially independent of the measurement value that the measuring probe is designed to determine. Thus, the determination of the ability of the probe to function correctly depends only on the probe-specific parameters.

The method according to a further exemplary embodiment also includes storing the calculated monitoring quantity in a memory. In addition, this quantity allows an estimate of the remaining operating life and/or of the state of aging of the measuring probe.

Thus, the exemplary method makes it possible to determine the stability of the measurement values and to estimate how strongly the measuring probe has aged and/or how much longer it is likely to perform its function, so that the time for exchanging the measuring probe can be determined more accurately. Furthermore, events that may for example lead to a regeneration of the measuring probe are also registered. A regeneration of the measuring probe can occur as an active or passive event. An active regeneration would consist for example of an exchange of the electrolyte of a pH-measuring probe or the replacement of the oxygen-permeable diaphragm of an oxygen measuring probe. A passive or accidental regeneration can occur for example also by the measurement media being used or by the measurement conditions and/or cleaning processes.

The remaining operating life or the state of aging of the measuring probe can be determined for example by comparing the current monitoring quantity with an optimum value for the same quantity as specified by the manufacturer of the measuring probe.

Based on the determination of at least two probe-specific parameters it is also possible to draw a conclusion about the ability of the measuring probe to function correctly. If the value of one parameter changes and there is no change in the other parameter occurring at or near the same time, the conclusion may be drawn that the measuring probe is no longer functioning optimally and should therefore be checked and, if necessary, exchanged. It can be a further symptom of a possible failure of the measuring probe, if at least one of the monitored parameters does not return, or returns too slowly, to a constant level after a disturbance. The user can be notified about incidents of this kind, possibly accompanied by suggestions on how to proceed.

In a further exemplary embodiment of the method, the stability of the measurement value is used as the monitoring quantity. Based on the recorded first and third point in time, a time window is determined in which the measuring probe delivers potentially unstable measurement values. It is advantageous if the user is alerted by an indication or a notice about this time window. Based on this information, the user can establish, either manually or by means of an appropriately adapted automated procedure, which measurement values were registered during this time window. These measurement values are potentially unstable or even false and can be marked accordingly, so that they can for example be disregarded in an evaluation of the results. The user is informed continuously and/or at the end of the measurement or the process about the episodes when the results are unstable and, conversely, he therefore also knows which measurement values were registered without this uncertainty and are therefore stable and reliable. This facilitates the identification of outliers and also provides an indication about the ability of the measuring probe to function properly.

The monitoring of the stability and reliability of the measurement values is relevant in particular for measuring probes which are used in the determination of critical components such as for example oxygen. The ability of an oxygen-measuring probe to function correctly should be ensured without interruption, particularly if the probe is used in areas where the presence of oxygen above a certain concentration could lead to an explosion. The assurance of correct functioning is also referred to as fail safety. The exemplary method according to the invention makes it possible to monitor the correct functioning of the probe as well as the reliability of the measurement values continuously and/or at given intervals. Defective measuring probes can be identified in a simple way and exchanged. Defective measurement values, likewise, can be checked at or near the same time with an additional external measuring probe, leading for example to safety improvements in areas with an explosion risk.

Every potentiometric measuring probe has different probe-specific parameters, most of which can be used in the method that has been described here. Factors to be considered in choosing the first and second parameters are that the value of the first parameter should respond faster to a change than the value of the second parameter and that the values of the parameters can be influenced by a change in the measurement medium. Possible combinations of a first and a second parameter include for example the oxidation-reduction potential (ORP) and a first glass value, (U_{glas1}−U_{SG}), of the measuring probe, a first reference value and a second reference value, the oxidation-reduction potential and a measurement value potential, or a first, fast glass value and a second, slow glass value.

It is particularly advantageous to carry out the method as a dynamic procedure which can be performed during operation of the measuring probe. This allows the method to be performed also while the process is running, whereby a continuous surveillance of the correct functioning of the measuring probe and of the reliability of the measurement values collected in the process is assured.

A measuring system designed to perform this method comprises a measuring probe, specifically an ion-sensitive, amperometric, potentiometric or optical measuring probe, with a transmitter and a controller, wherein the measuring probe is in contact with a measurement medium and the controller comprises a computer unit and at least one program designed to implement the method.

The measuring probe in an exemplary embodiment is a potentiometric measuring probe with a reference electrode and at least one ion-sensitive glass.

In a further embodiment, the controller and the transmitter form a common unit.

### BRIEF DESCRIPTION OF THE DRAWINGS

In addition to the features mentioned above, other aspects of the exemplary methods according to the invention as well as exemplary measuring systems will be readily apparent from the following descriptions of the drawings and exemplary embodiments, wherein like reference numerals across the several views refer to identical or equivalent features, and wherein:

FIG. 1 is a time graph of a first and a second parameter value of a measuring probe;

FIG. 2 is a schematic flowchart of a exemplary method of monitoring a potentiometric measuring probe by keeping track of a first and second parameter value; and

FIG. 3 represents a time graph of the ORP-value and the pH-value of two measuring probes (InPro 3250SG with M700) during the process of adding hydrochloric acid to an aqueous solution of pH 7.

### DETAILED DESCRIPTION OF EXEMPLARY EMBODIMENTS

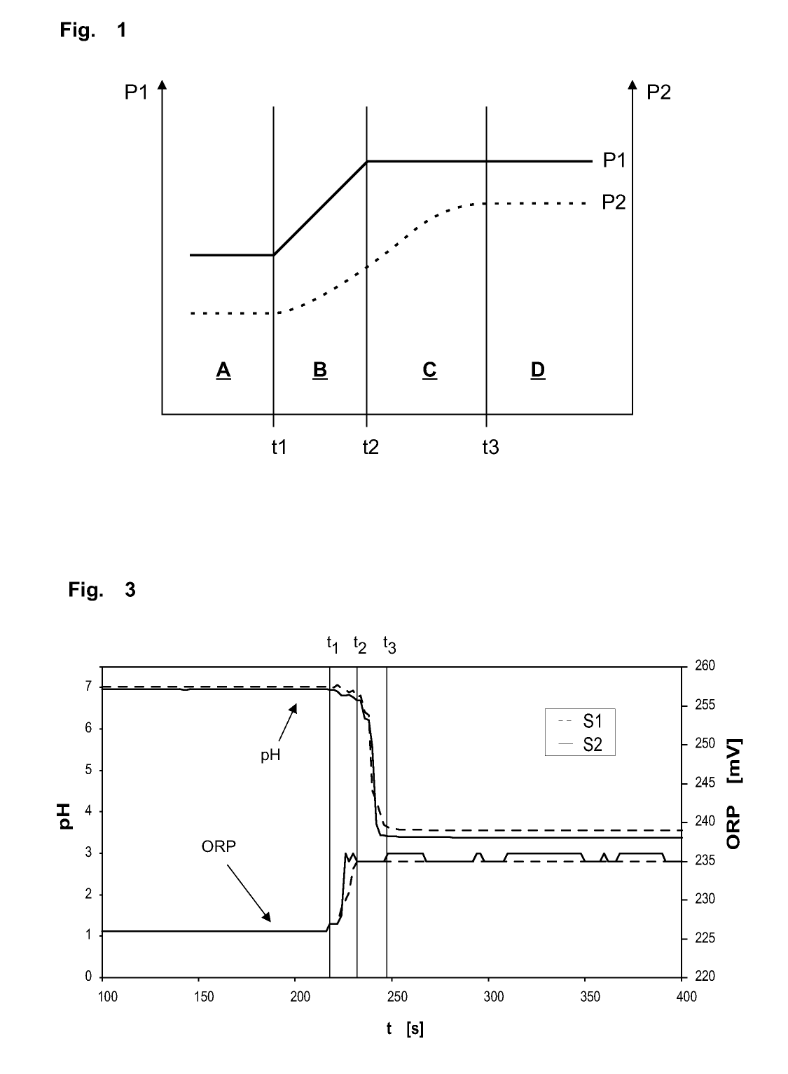

FIG. 1 schematically illustrates the time profiles of a first parameter P1 and a second parameter P2 during a process in which changes are taking place. Both of the parameters P1, P2 are probe-specific parameters which are in essence independent of each other. The changes of the values of these parameters P1, P2 can for example give an indication of the stability and/or reliability of measurement results and/or about the ability of the measuring probe to function correctly.

During a first time interval A, the values measured for both of the parameters P1, P2 are essentially constant, which leads to the conclusion that the measurement medium, too, is essentially constant in its composition and the acquisition of measurement values by the measuring probe takes place under essentially constant conditions.

However, if a change occurs in the process, for example with the addition of further reagents and/or due to a change of the process parameters, this will also have an effect on the measuring probe. The probe-specific parameters P1, P2 react to this change. The point in time t1 indicates that a change or disturbance of this type is occurring in the measurement medium. As the time interval B in the diagram shows, the first parameter P1 responds very quickly to the disturbance. The values of the first parameter P1 indicate a quick response to the change in the measurement medium. At the time t2, the first parameter P1 has already found a stationary level again and continues at an essentially constant value.

The second parameter P2 also reacts to the disturbance of the measurement medium, but more slowly, as can be seen in the time intervals B and C. At the time t2 the value of the second parameter P2 is still unstable, and it takes until the time t3 for the second parameter P2 to again find an essentially constant level, which is then achieved as seen in time interval D.

The second parameter P2 also reacts to the disturbance of the measurement medium, but more slowly, as can be seen in the time intervals B and C. At the time t2 the value of the second parameter P2 is still unstable, and it takes until the time t3 for the second parameter P2 to again find an essentially constant level.

The result of the determination of the two parameters P1, P2 also allows a diagnosis to be made on the ability of the measuring probe to function correctly. If the value of one of the two parameters P1, P2 changes while at the same time there is no change in the other parameter, one can conclude that the measuring probe is no longer functioning optimally and that an inspection and/or an exchange should be made. It can be a further indication of a possible failure of the measuring probe, if the first and/or the second of the parameters P1, P2 does not return, or returns too slowly, to an essentially constant level after a disturbance. Incidents of this kind are indicated to the user, preferably on the same display panel which also shows the measurement values. Of course, it is also possible that this message is passed on to a higher-level system, for example a control center.

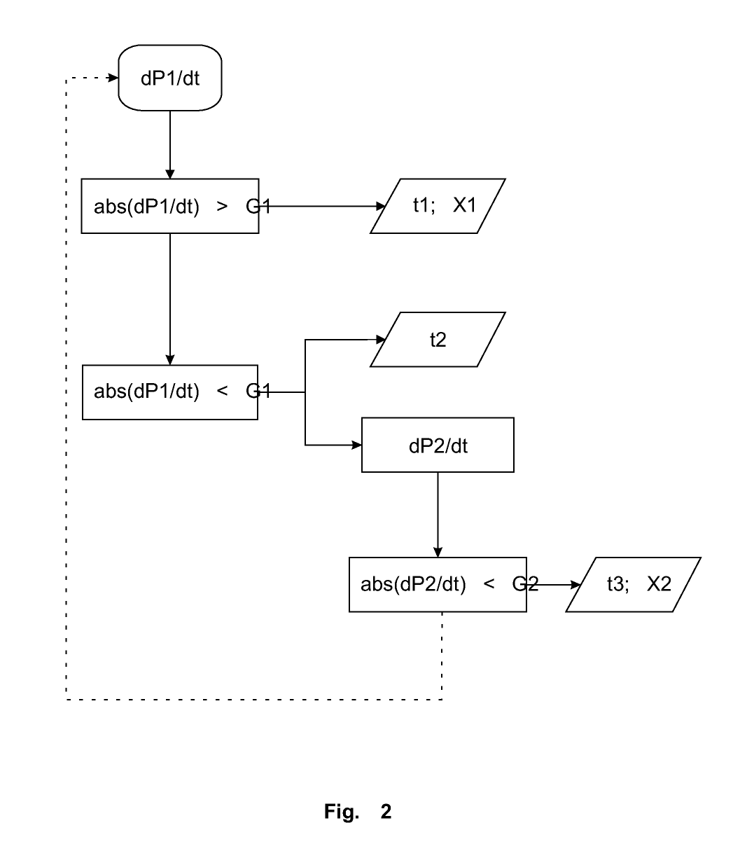

The flowchart of FIG. 2 schematically represents an exemplary method according to the invention based on the behavior of the parameters P1, P2 as shown in FIG. 1.

In parallel with the measurement value of the measuring probe, the value of the first parameter P1 is likewise registered as a function of the time t. The time derivative or slope of this function is determined and a first absolute value |dp1/dt| is determined. This first absolute value |dp1/dt| is compared to a first threshold value G1. If the first absolute value |dp1/dt| is greater than the first threshold value G1, a first point in time t1 is registered which represents essentially the point in time when a disturbance occurred in the process. As shown in FIG. 1, the first point in time t1 indicates the start of the transient phase of the first parameter P1. In addition, a first measurement value X1 of the measuring probe can also be registered.

Starting with the first point in time t1, the value of the first parameter P1 is registered as a function of time until the first absolute value |dP1/dt|, which is shown in FIG. 2 as abs(dP1/dt), has fallen again below the first threshold value G1, i.e. until the value of the first parameter P1 is again essentially constant. The second point in time t2 when this happens is again registered.

The second point in time t2 indicates the point in time when the first parameter P1 settled down again to an essentially constant level. From the time t2 on, the transient behavior of the second parameter P2 in its approach to an essentially constant level is monitored by registering its value as a function of time. A second absolute value |dP2/dt|—or abs(dP2/dt) in FIG. 2—is established from the time derivative of the value of the second parameter P2. This second absolute value |dP2/dt| is compared to a second threshold value G2. The second parameter P2 is kept under surveillance until the second absolute value |dP2/dt| is smaller than the threshold value G2. The third point in time t3 when this happens denotes the point in time at which the two parameters P1, P2 have settled into essentially constant values and the measuring system runs in a stable mode. At the time t3 of the third point in time, a second measurement value X2 can be measured.

Measurements made in the time interval between the first point in time t1 and the third point in time t3 are subject to a measurement uncertainty, as the process was disturbed and the measuring probe has not yet adapted itself to the new conditions. This time interval is brought to the attention of the user and represents a first monitoring quantity.

The combined time intervals B and C in FIG. 1 further provide information regarding the response behavior of the measuring probe, which represents a further monitoring quantity. The measuring probe requires this time interval in order to settle into a steady state after a disturbance of the measurement medium. Experience has shown that the response behavior slows down with increasing deterioration of the measuring probe over its operating life.

If the magnitude of the step between the first and second measurement values X1, X2 that is associated with the disturbance is known, the remaining operating life or the state of aging of the measuring probe can be estimated and/or determined based on the current value of the monitoring quantity determined with the method and by comparing the latter to a given optimal value of the monitoring quantity.

In addition, based on the measurement values from the experiment, a fourth and/or fifth point in time can be calculated, where the measurement value of the probe reaches, respectively, about 95% and about 98% of the total step size of the measurement value, i.e. of the difference between the first and the second measurement value. By means of the fourth and/or fifth point in time, a probe-specific quantity can be determined which allows a conclusion to be drawn about the response time and thus also about the state of aging of the measuring probe.

Of course, all of the values determined in the method can be seen on a readout and evaluated, or they can be electronically stored in a suitable form and processed. The stored values can be automatically evaluated and/or used for a retrospective analysis of potential measurement errors.

The first parameter P1 is preferably determined simultaneously with each measurement value as a function of time. The second parameter P2 can be determined for example only between the times t1 and/or t2 and t3, or it can be determined simultaneously with each measurement value like the first parameter P1. Depending on the measuring probe being used, it is also conceivable that the measurement value X and/or the parameter values P1, P2 are determined continuously.

FIG. 3 shows a time graph of the ORP- and pH-values of two measuring probes S1, S2 for the process of adding hydrochloric acid to an aqueous solution of pH7. Both of the probes S1, S2 are potentiometric measuring probes made by Mettler-Toledo of the type InPro 3250SG which were operated in conjunction with a transmitter M700. The time graphs of the ORP- and pH-values of the first measuring probe S1 are drawn in broken lines, and the time graphs of the ORP- and pH-values of the second measuring probe S2 are drawn in solid lines. As is evident from FIG. 3, the ORP-value of both measuring probes S1, S2 responds faster than the pH-value to the addition of concentrated acid to the buffer. The ORP-values exhibit a step change at the time t1 and are already essentially constant again at the time t2. The pH-values of both measuring probes S1, S2, in contrast, exhibit a delayed response to the addition of the acid. In essence, the pH-step occurs only between the times t2 and t3. At the time t3, the ORP- and pH-values of both measuring probes S1, S2 have settled again and show essentially constant values.

Thus, the exemplary method according to the invention provides a user-friendly and automatic way to analyze the changes of the probe-specific parameters shown in FIG. 3 which occur as a result of a disturbance of the measurement medium.

Although the invention has been described by presenting specific exemplary embodiments, it is evident that numerous further variants could be created based on a knowledge of the present invention, for example by combining the features of the individual examples of embodiments with each other and/or by interchanging individual functional units between the embodiments.

What is claimed is:

1. A method of monitoring, in a process system, the operational quality of a measuring probe used to acquire measurement values of a first and a second parameter of a measurement medium of the process system, the measurement values being used in a controller associated with the process system, the first and second parameters being probe-specific, the first and second parameter being selected such that the first parameter responds more quickly than the second parameter to changes in the measurement medium, the method comprising the steps of:
acquiring, with the measuring probe, time-dependent values of the first parameter and the second parameter;
receiving, at the controller, the acquired time-dependent values of the respective parameters;
establishing, in a computer unit of the controller, a first time point by the substeps of:
determining a first absolute value, defined as the absolute value of a time derivative of the acquired time dependent values of the first parameter;
comparing the first absolute value to a first threshold value; and
when the first absolute value exceeds the first threshold value, registering the time as the first time point;
establishing, also in the computer unit, a second time point, after the first time point, by the substeps of:
determining the first absolute value;
comparing the first absolute value to the first threshold value; and
when the first absolute value falls below the first threshold value, registering the time as the second point in time;
establishing, also in the computer unit, a third time point by the substeps of:
determining a second absolute value, defined as the absolute value of a time derivative of the acquired time dependent values of the second parameter;
comparing the second absolute value to a second threshold value; and
when the second absolute value falls below the second threshold value, registering the time as the third time point; and
determining a monitoring quantity of the measuring probe in the computer as a function of the time intervals between the respective first through third time points.

2. The method of claim 1, further comprising the step of:
comparing the relative response of the at least one measurement value of two or more probe-specific parameters.

3. The method of claim 1, wherein a monitoring quantity is a relative response of the measuring probe, the relative response determined by:
registering a first measurement value at the first time point;
registering a second measurement value at the third time point;
determining the difference between the registered first and second measurement values; and
determining the time interval between the first time point and the third time point.

4. The method of claim 1, further comprising the steps of:
establishing, also in the computer unit, a fourth time point by the substeps of:
determining a 95% measurement value defined as a value at which the measurement value reaches 95% of the difference between the first and second measurement values;
comparing the measurement values to the 95% measurement value; and
registering the time at which the measurement value is equal to the 95% measurement value; and
calculating a probe-specific quantity based on the fourth time point.

5. The method of claim 4, further comprising the steps of:
establishing a fifth time point by the substeps of:
determining a 98% measurement value defined as a value at which the measurement values reaches 98% of the difference between the first and second measurement values;
comparing the measurement values to the 98% measurement value; and
registering the time at which the measurement value is equal to the 98% measurement value; and
calculating the probe-specific quantity based on the fifth time point.

6. The method of claim 1, further comprising:
storing the monitoring quantity in a memory; and
determining a remaining operating life of the measuring probe based upon the stored monitoring quantity.

7. The method according to claim 6, wherein
the remaining life is determined by comparing a current value of the monitoring quantity to a predetermined optimal value for the monitoring quantity.

8. The method of claim 1, wherein:
the monitoring quantity is a stability of the measurement values wherein, based on the first and third time points that were registered, a time window is defined during which the measuring probe delivers measurement values in which at least one of the first and second absolute rate of change exceeds the corresponding threshold value, and wherein the time window is brought to the attention of a user.

9. The method of claim 1, wherein said first parameter is an oxidation-reduction potential and the second parameter is a first glass value.

10. The method of claim 1, wherein said first parameter is a first reference value and the second parameter is a second reference value.

11. The method of claim 1, wherein said first parameter is an oxidation-reduction value potential and the second parameter is a measurement value potential.

12. The method of claim 1, wherein said first parameter is a first glass value and the second parameter is a second glass value.

13. The method of claim 1, wherein said method is a dynamic method performed while the measuring probe is in operation.

14. A measuring system designed to perform the method of claim 1, comprising:
a measuring probe in contact with a measurement medium; and
a transmitter having a controller, said controller includes a computer unit and at least one program designed to carry out the method of claim 1.

15. The measuring system of claim 14, wherein the measuring probe is selected from the group consisting of: an ion-sensitive, an amperometric, a potentiometric and an optical measuring probe.

16. The measuring system of claim 14, wherein the measuring probe is a potentiometric measuring probe with a measuring electrode, at least one reference electrode and at least one ion-sensitive glass.

17. The measuring system of claim 14, wherein the controller and said transmitter form a common unit.
